(19) United States
(12) Patent Application Publication
(10) Pub. No.: US 2013/0181240 A1
(43) Pub. Date: Jul. 18, 2013

(54) COMPOSITE SUBSTRATE, MANUFACTURING METHOD THEREOF AND LIGHT EMITTING DEVICE HAVING THE SAME

(71) Applicants: Crystalwise Technology Inc., Hsinchu County (TW); Ming-Jang Chen, Taipei City (TW)

(72) Inventors: MIIN-JANG CHEN, TAIPEI CITY (TW); MING-CHIH LIN, NEW TAIPEI CITY (TW); WEN-CHING HSU, HSINCHU (TW)

(73) Assignees: CRYSTALWISE TECHNOLOGY INC., Hsinchu County (TW); MIN-JANG CHEN, Taipei City (TW)

(21) Appl. No.: 13/744,474

(22) Filed: Jan. 18, 2013

(30) Foreign Application Priority Data
Jan. 18, 2012 (TW) 101101949

(51) Int. Cl. H01L 33/00; H01L 33/02

(52) U.S. Cl. CPC H01L 33/005; H01L 33/02
USPC 257/94; 428/446; 428/698; 428/432; 427/248.1; 427/569; 423/412; 423/409

(57) ABSTRACT

The present invention relates to a manufacturing method of a composite substrate. The method includes the steps of: providing a substrate; providing a precursor of group III elements and a precursor of nitrogen (N) element alternately in an atomic layer deposition (ALD) process or a plasma-enhanced atomic layer deposition (PEALD) process so as to deposit a nitride buffer layer on the substrate; and annealing the nitride buffer layer on the substrate at a temperature in the range of 300° C. to 1600° C.

### BACKGROUND OF THE INVENTION

1. Field of the Invention

The present invention relates to a composite substrate, a manufacturing method thereof, and a light emitting device having the same; more particularly, to a composite substrate having a buffer layer, a manufacturing method thereof, and a light emitting device having the same.

2. Description of Related Art

The field of photoelectric devices has gained much popularity in Taiwan over recent years. For example, the production value of photoelectric devices such as semiconductors and light-emitting diodes (LEDs) is among the top globally. Application-wise, semiconductor such as gallium nitride (GaN) is applicable to short wavelength light emitting application. Serious research work has been performed for GaN. Generally, the GaN uses sapphire as a substrate in forming multiple thin films thereon, through the method of metal-organic chemical vapor deposition (MOCVD) or molecular beam epitaxy (MBE).

More specifically, a buffer layer is first formed on the substrate. Then a n-type GaN layer, an indium gallium nitride (InGaN) light emitting layer, and a p-type GaN layer are grown epitaxially and sequentially on the buffer layer. Thus, an LED can be manufactured. Notably, the sandwiched buffer layer is capable of improving the quality of the epitaxial layers, hence raising the light efficiency of the light emitting devices.

Traditionally, the buffer layer is usually formed by the MOCVD process; for example, an organic metal and a nitrogen (N) element are reacted with each other to form a nitride buffer layer on the substrate. However, the operation temperature of the MOCVD is high, which means high energy consumption and higher possibility of equipment damage. Moreover, the buffer layer—particularly a buffer layer of GaN material, is more difficult to grow by the MOCVD process, and the quality of the grown buffer layer is difficult to control. Accordingly, the qualities and performance of the semiconductor light emitting devices have greater instability.

### SUMMARY OF THE INVENTION

One object of the instant disclosure is to provide a manufacturing method of a composite substrate. The method uses the atomic layer deposition (ALD) technique or the plasma-enhanced atomic layer deposition technique (PEALD) to deposit a nitride buffer layer under optimized conditions. The formed nitride buffer layer has a high quality and is applicable in providing improved semiconductor light emitting devices.

The method comprises the following steps: providing a substrate (step 1); alternately providing a precursor of group III elements and a precursor of N element to deposit a nitride buffer layer on the substrate through the ALD or PEALD process (step 2); and annealing the nitride buffer layer within a temperature range from 300 to 1600° C. (step 3).

The instant disclosure also provides a composite substrate having a substrate and a nitride buffer layer deposited thereon. The nitride buffer layer is formed by an atomic layer deposition (ALD) process or a plasma-enhanced atomic layer deposition (PEALD) process followed by an annealing process.

The instant disclosure further provides a light emitting device comprising a composite substrate and an epitaxial structure. The composite substrate includes a substrate and a nitride buffer layer deposited thereon. The nitride buffer layer is formed by an atomic layer deposition (ALD) process or a plasma-enhanced atomic layer deposition (PEALD) process followed by an annealing process. The epitaxial structure is formed on the nitride buffer layer of the composite substrate.

By applying the ALD or PEALD process, which is self-limiting, the high quality nitride buffer layer can be grown in a low-temperature condition and in a layer-by-layer manner with excellent stability and uniformity. The formed composite substrate can be used to manufacture improved light emitting devices having better performance.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1 is a schematic view showing a composite substrate of the instant disclosure.

FIG. 2 is a schematic view showing a light emitting device of the instant disclosure.

FIG. 3 is a plot showing a buffer layer growth rate as a function of a pulse time for one deposition cycle of a manufacturing method of the instant disclosure.

FIG. 4 is a plot showing the buffer layer growth rate as a function of a hydrogen flowrate for one deposition cycle of the manufacturing method of the instant disclosure.

FIG. 5 is a plot showing the buffer layer growth rate as a function of an ammonia flowrate for one deposition cycle of the manufacturing method of the instant disclosure.

FIG. 6A shows the growth rate of a GaN buffer layer deposited on a Si (100) substrate as a function of the substrate temperature ranging from 200˜500° C. according to the instant disclosure.

FIG. 6B shows the growth rate of the GaN buffer layer deposited on a Si (111) substrate as a function of the substrate temperature ranging from 200 to 500° C. according to the instant disclosure.

FIG. 6C shows the growth rate of the GaN layer deposited on a sapphire substrate as a function of the substrate temperature ranging from 200 to 500° C. according to the instant disclosure.

FIG. 7A shows the X-ray diffraction patterns of the GaN layer deposited on the Si (100) substrate for different substrate temperatures according to the instant disclosure.

FIG. 7B shows the X-ray diffraction patterns of the GaN layer deposited on the Si (111) substrate for different substrate temperatures according to the instant disclosure.

FIG. 7C shows the X-ray diffraction patterns of the GaN layer deposited on the sapphire substrate for different substrate temperatures according to the instant disclosure.

FIG. 8A shows a XPS spectrum of a 3d orbital of gallium (Ga) of the GaN buffer layer of the instant disclosure.

FIG. 8B shows a XPS spectrum of a 1s orbital of nitrogen (N) of the GaN buffer layer of the instant disclosure.

### DETAILED DESCRIPTION OF THE PREFERRED EMBODIMENTS

The instant disclosure provides a composite substrate, a manufacturing method thereof, and a light emitting device having the same. The composite substrate may be used for growing epitaxial layers thereon for applications such as LEDs, laser diodes, or light detection devices. The manufacturing method of the composite substrate utilizes a low-temperature process to grow a buffer layer on a substrate. The grown buffer layer has a multi-atomic layered structure. The atomic layers are orderly arranged with excellent uniformity.

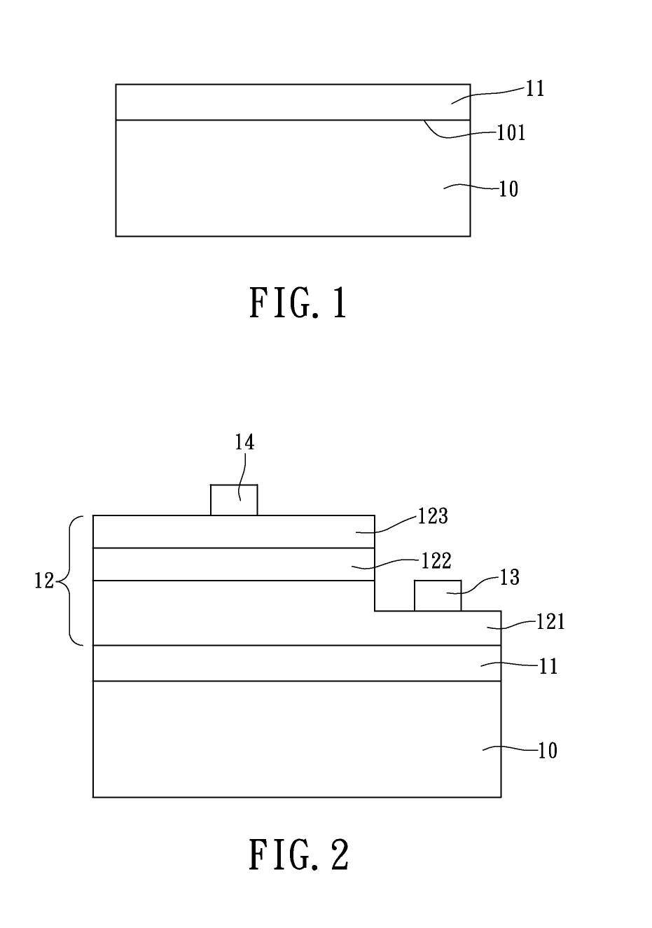

Please refer to FIG. 1. The manufacturing method comprises the following steps:

Step 1: providing a substrate 10 which can be a material such as sapphire, silicon (Si), silicon carbide (SiC), gallium nitride (GaN), zinc oxide (ZnO), gallium arsenide (GaAs), scandium magnesium aluminate (ScAlMgO₄), strontium copper oxide (SrCu₂O₂/SCO), lithium dioxogallate (LiGaO₂), lithium aluminate (LiAlO₂), yttria-stabilized zirconia (YSZ), glass, or any other material suitable for growing epitaxial structure thereon.

Step 2: is alternately providing a precursor of group III elements and a precursor of nitrogen (N) element to deposit a nitride buffer layer 11 on the substrate 10 by an atomic layer deposition (ALD) process or a plasma-enhanced atomic layer deposition (PEALD) process. In this step, the ALD or PEALD process is applied to grow the nitride buffer layer 11 on a surface 101 of the substrate 10. The ALD process, also referred to as the thermal atomic layer deposition process, utilizes pulses of gas to cause a chemical reaction between two or more reactants (i.e., the precursors). As for the PEALD process, also known as plasma-assisted atomic layer deposition, plasma is employed to initiate the chemical reaction. Regardless their differences, both methods can be performed at low-temperature conditions to reduce energy consumption and heat-induced equipment issues. Furthermore, the ALD/PEALD process is self-limiting in yielding one submonolayer of film per deposition cycle. In addition, the formed film is precisely controlled as a pinhole-free structure. In conclusion, the ALD/PEALD process adopted by the instant invention has the following advantages: (1) able to control the film thickness more precisely; (2) able to have large-area production; (3) having excellent uniformity; (4) pinhole-free structure; (5) having low defect density; and (6) having high process stability.

In the ALD/PEALD process, two precursors are alternately introduced onto the reacting surface 101. Between the injections of two precursors, inert gases are introduced into the reaction chamber, while non-reacted precursor and the gaseous reaction by-products are removed. The forward precursor preferably is highly reactive to perform chemical absorption on the surface 101 of the substrate 10 and then to react with the trailing precursor. For the case of the nitride buffer layer 11, each reaction cycle of the ALD/PEALD process includes the following sub-steps:

Step a): a N forward precursor, such as ammonia (NH₃), is introduced into the reaction chamber and absorbs onto the surface 101 of the substrate 10. A single layer of N-H group is formed on the surface 101 of the substrate 10. The pulse time of the forward precursor is about 0.1 second. Because of the self-limiting absorption behavior of the forward precursor, the excess precursor molecules are purged out of the reaction chamber.

Step b): introducing a carrier gas to remove any excess precursor molecules from the reaction chamber. The carrier gas may be highly purified N or argon (Ar), with a purge time ranging from about 2 to 10 seconds. Through the use of inert gas like N or Ar and a pumping tool, excess precursor molecules and gaseous reaction by-products are removed from the reaction chamber.

Step c): introducing a trailing precursor of group III elements, such as triethylgallium (Ga(C₂H₅)₃) molecules, into the reaction chamber. The trailing precursor reacts with the single layer of N-H group absorbed on the surface 101 of the substrate 10. The pulse time of the trailing precursor is about 0.1 second. Thus, one monolayer of GaN layer (i.e., the nitride buffer layer 11) is formed on the surface 101 of the substrate 10, along with some organic molecules by-products. The surface of the formed nitride buffer layer 11 serves as a new reaction surface for the next deposition cycle.

Step d): introducing an inert gas and using a pumping tool to purge excess second precursor molecules and gaseous reaction by-products from the reaction chamber.

Therefore, by repeating the above four steps of the deposition cycle, where the two reacting precursors are alternately introduced onto the reacting surface 101, and controlling the number of deposition cycles, the thickness of the nitride buffer layer 11 can be precisely controlled. With the layer-by-layer growth, the grown nitride buffer layer 11 is of high-quality grade with good stability and uniformity.

For depositing a GaN layer as the nitride buffer layer 11, the precursor of group III elements may be trimethylgallium (TMGa), triethylgallium (TEGa), gallium tribromide (GaBr₃), gallium trichloride (GaCl₃), triisopropylgallium, or tris(dimethylamido) gallium. Whereas the N precursor may be ammonia (NH₃), ammonia plasma, or nitrogen-hydrogen plasma.

In another embodiment, the nitride buffer layer 11 may be an alumina nitride (AlN) layer. For such case, the precursor of group III elements may be aluminum sec-butoxide, aluminum tribromide, aluminum trichloride, diethylaluminum ethoxide, tris(ethylmethylamido)aluminum, triethylaluminum, triisobutylaluminum, trimethylaluminum, tris(diethylamido)aluminum, tris(dimethylamino)aluminum, tris(ethylmethylamido)aluminum. Similarly, the N precursor may be (NH₃), ammonia plasma, or nitrogen-hydrogen plasma.

In still another embodiment, the nitride buffer layer 11 may be an indium nitride (InN) layer. For depositing the InN layer, the precursor of group III elements may be trimethylindium (TMIn), indium(III)acetylacetonate, indium(I)chloride, indium(III)acetate hydrate, indium(II)chloride, or indium(III)acetate. Whereas the N precursor may be NH₃, ammonia plasma, or nitrogen-hydrogen plasma.

Step 3: annealing the formed nitride buffer layer 11 at a temperature ranging from 300° C. to 1600° C. A preferable range is from 400° C. to 1200° C. The annealing step is applied to improve the crystalline qualities of the nitride buffer layer 11.

Some experimental statistics regarding the nitride buffer layer 11 of GaN is provided hereinbelow. The experiment is performed using the PEALD process, where the GaN layer is formed on three types of substrate 10, namely a Si (100) substrate, a Si (111) substrate, and a sapphire substrate. The precursor of group III elements is triethylgallium (Ga(C₂H₅)₃, or TEGa) and the N precursor is NH₃. Hydrogen (H₂) is introduced into the reaction chamber to enhance the chemical reaction. The experimental parameter and conditions are shown below:

| | |
|---|---|
| substrate temperature | 200° C.-500° C. |
| pulse time of TEGa | 0.03-0.25 sec. |
| plasma power | 300 W |
| gas flow rate | NH₃ = 15-45 sccm |
| | H₂ = 0-10 sccm |
| number of ALD cycles | 600 |
| plasma time | 10-60 sec |

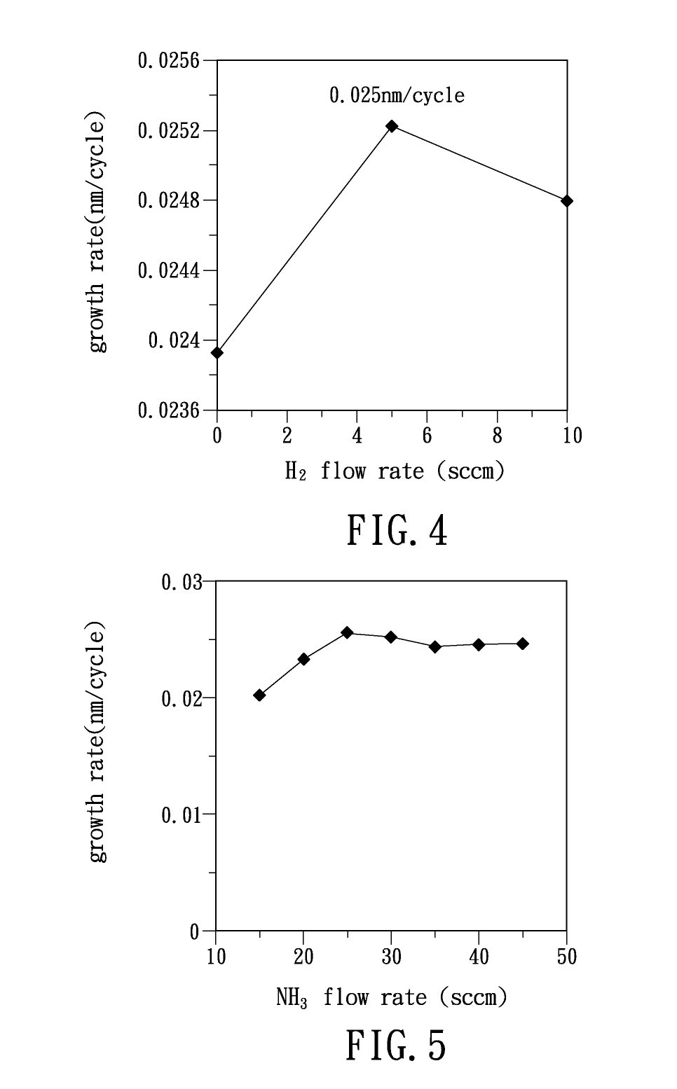

Please refer to FIG. 3, which shows the growth rate of the nitride buffer layer 11 of GaN on the Si (100) substrate 10 at 200° C. as a function of the pulse time. The growth rate reaches a maximum value of about 0.025 nm/cycle when the pulsing time is about 0.1 second and exhibits a self-limiting behavior.

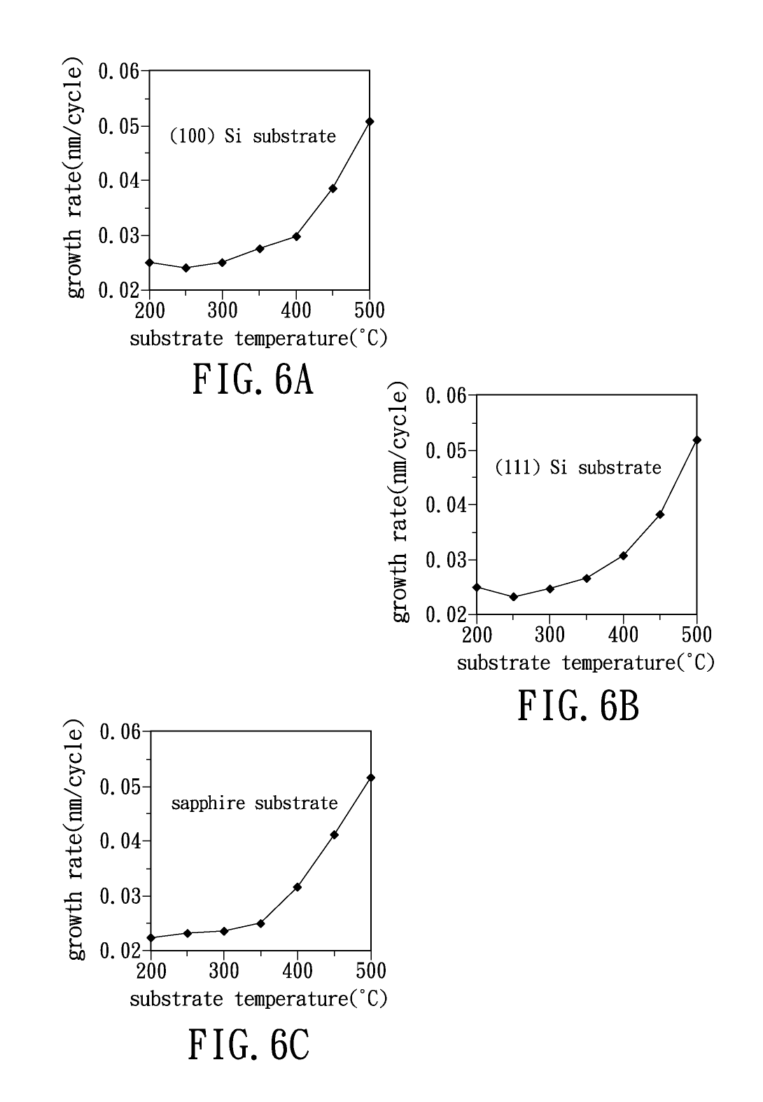

Please refer to FIG. 4, which shows the growth rate of the nitride buffer layer 11 of GaN on the Si (100) substrate 10 at 200° C. as a function of the H₂ flowrate. The growth rate varies from about 0.0239 to 0.0252 nm/cycle for a flowrate of H₂ ranging from 0 to 10 sccm. A maximum growth rate is reached at about 0.025 nm/cycle when the flowrate of H₂ is about 5 sccm. The reason being a proper amount of H₂ flowrate can promote molecular dissociation of NH₃ in reacting with Ga ions to deposit the GaN buffer layer 11. However, when the H₂ flowrate is too high, such as at 10 sccm, the growth rate of the GaN buffer layer 11 is suppressed.

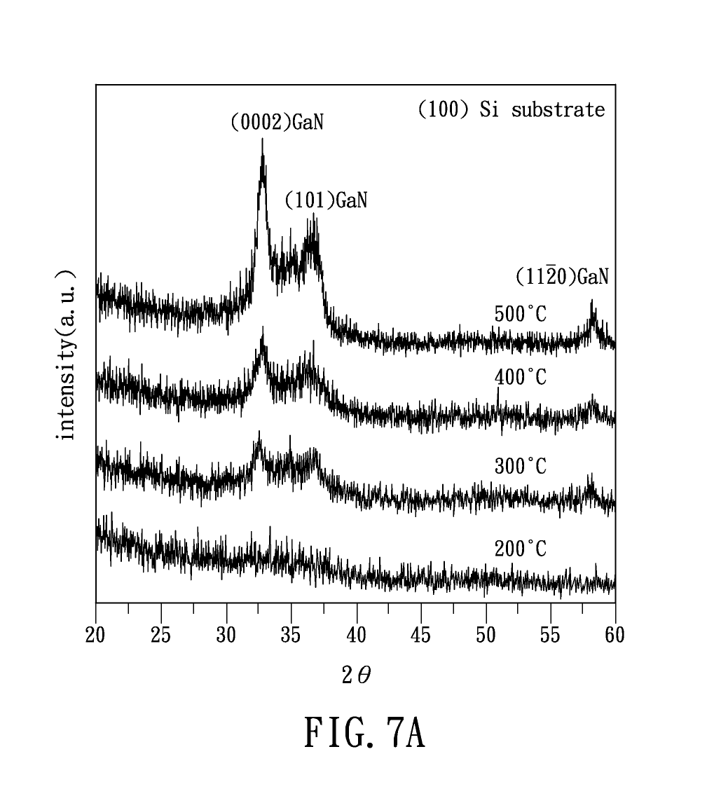

Please refer to FIG. 5, which shows the growth rate of the nitride buffer layer 11 of GaN on the Si (100) substrate 10 at 200° C. as a function of the NH₃ flowrate. The maximum growth rate occurs when the NH₃ flowrate is about 25 sccm. Meanwhile, when the NH₃ flowrate is ranged from 15 to 45 sccm, the growth rate of the GaN buffer layer is ranged from about 0.020 to 0.025 nm/cycle. The data suggests when the NH₃ flowrate is about 25 sccm, there are enough N atoms to react with Ga atoms. A higher NH₃ flowrate does not increase the growth rate of the GaN buffer layer. Such behavior reflects the self-limiting characteristic of the deposition process.

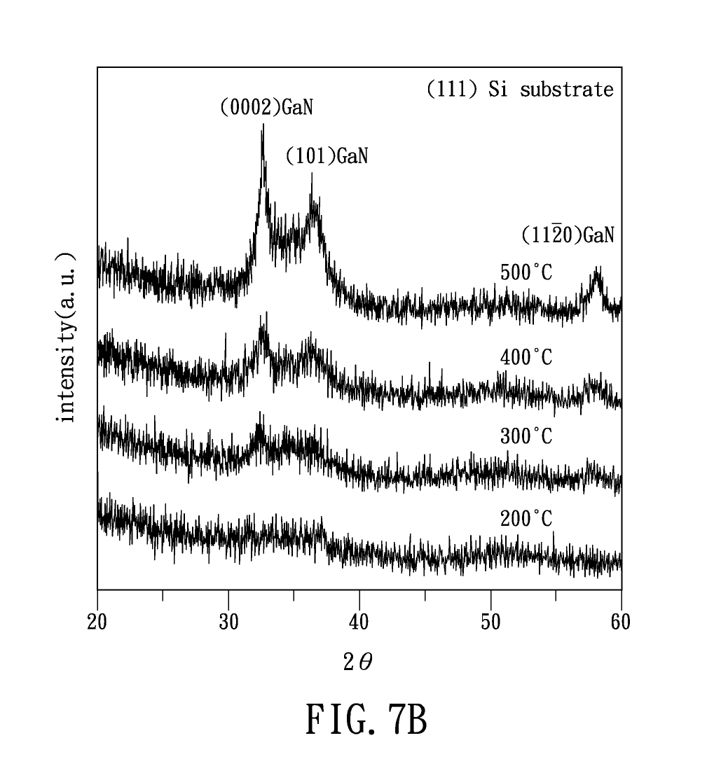

Please refer to FIGS. 6A to 6C, which show the growth rate of the buffer layer 11 on different substrates 10 at different temperatures for a single deposition cycle of the ALD process. Specifically, FIG. 6A shows the growth rate of the GaN buffer layer 11 deposited on the Si (100) substrate 10 under a substrate temperature ranging from 200 to 500° C. As shown in FIG. 6A, when the substrate temperature increases, the growth rate of the GaN buffer layer 11 also increases in showing a direct relationship therewith. The process achieves a maximum growth rate of 0.05 nm/cycle, which is obtained when the substrate 10 is heated to approximately 500° C. FIG. 6B shows the growth rate of the GaN buffer layer 11 deposited on the Si (111) substrate 10 having a temperature ranging from 200 to 500° C. As shown in FIG. 6B, the growth rate behavior is similar to the results shown in FIG. 6A. The maximum growth rate is about 0.052 nm/cycle, which is obtained when the substrate 10 is heated to 500° C. Furthermore, a similar growth rate behavior is observed in FIG. 6C. The maximum growth rate is about 0.052 nm/cycle, which is obtained when the sapphire substrate 10 is heated to about 500° C. The experimental data implies even for different substrate materials, particularly for a substrate temperature ranging from 200 to 500° C., a higher temperature means a greater growth rate of the GaN buffer layer. The reason may be that the higher substrate temperature provides greater reaction energy to enhance the chemical reactions of ammonia, thus increasing the growth rate of the GaN buffer layer.

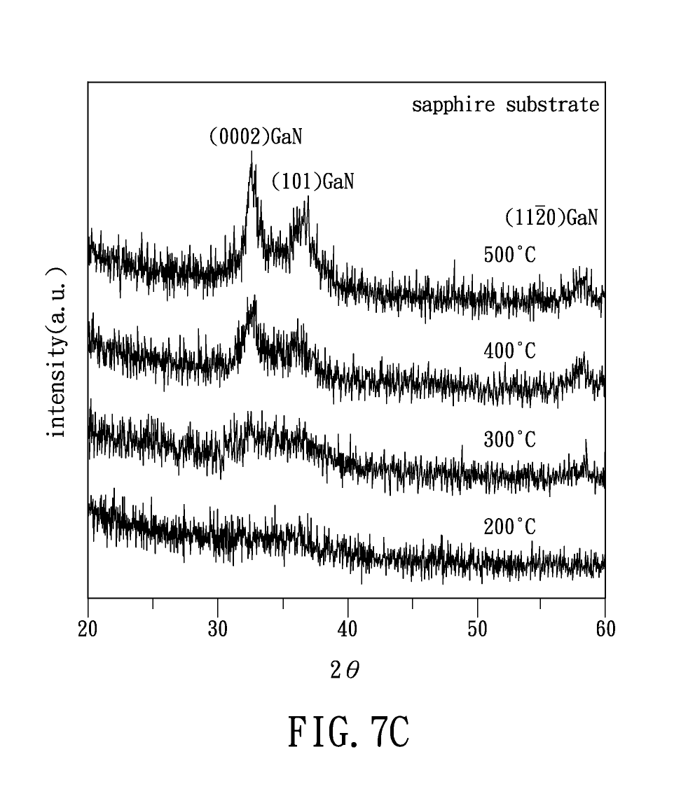

Please refer to FIGS. 7A to 7C, which show the crystalline property of the GaN buffer layer on different substrates 10 at different temperatures. FIG. 7A shows the grazing incidence X-ray diffraction scan of the GaN buffer layer deposited on the Si (100) substrate 10 having a temperature ranging from 200 to 500° C. As shown in FIG. 7A, the deposited GaN buffer layer is amorphous when the substrate temperature is about 200° C. However, when the substrate 10 is heated to at least 300° C., the GaN buffer layer begins to exhibit polycrystalline characteristic having crystal orientations of (0002), (101), and (10-20). FIGS. 7B and 7C show the grazing incidence X-ray diffraction scans of the GaN buffer layer deposited on the Si (111) and sapphire substrates 10, respectively. The results are similar to FIG. 7A. In other words, for different types of substrate 10, when the temperature of the substrate 10 is raised to at least 300° C., the buffer layer 11 having a polycrystalline structure can be grown.

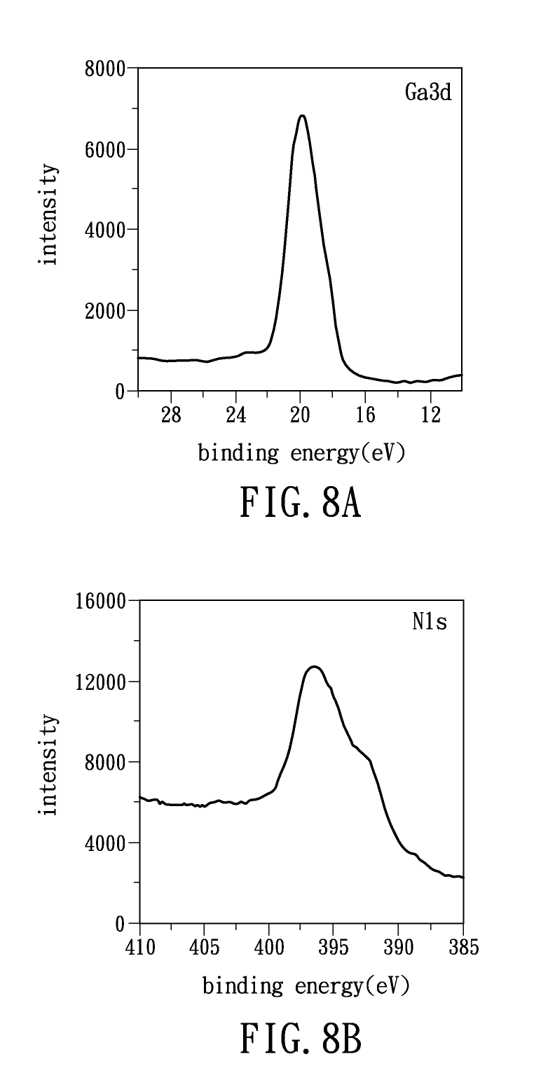

Please refer to FIGS. 8A and 8B, which show XPS (X-ray photoelectron spectroscopy) spectra for analyzing the binding energy of the buffer layer 11. The analysis can be used to determine the elemental composition, chemical state, and electronic state of the elements that exist within the deposited buffer layer 11. Specifically, FIG. 8A shows the XPS spectrum focusing on the 3d orbital of gallium (Ga). Whereas FIG. 8B shows XPS spectrum focusing on the 1s orbital of nitrogen (N). Based on the XPS, the deposited buffer layer 11 is deemed to be the GaN layer.

By performing the above steps, the composite substrate shown in FIG. 1 may be manufactured. This composite substrate is formed by depositing the nitride buffer layer 11 on the substrate 10. The nitride buffer layer 11 is deposited by the ALD or PEALD method. Furthermore, the nitride buffer layer 11 is annealed to improve its crystalline quality. Thereby, the formed nitride buffer layer 11 can have properties of high quality, high stability, and high uniformity.

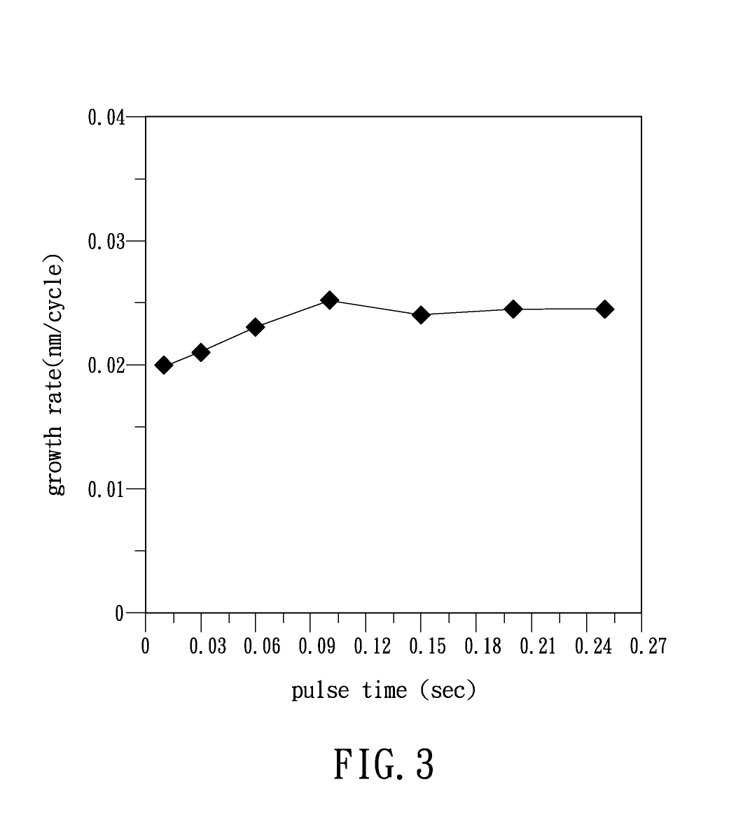

Please refer to FIG. 2, which shows a light emitting device utilizing the aforementioned composite substrate of the instant disclosure. The light emitting device comprises a composite substrate, which is formed by the substrate 10 and the nitride buffer layer 11. Moreover, an epitaxial structure 12 is formed on the composite substrate by a method of epitaxial layer growth. The epitaxial structure 12 includes a first type semiconductor layer 121 formed on the nitride buffer layer 11, a light emitting layer 122 formed on the first type semiconductor layer 121, and a second type semiconductor layer 123 formed on the light emitting layer 122. Furthermore, the light emitting device may further includes a first electrode 13 electrically connected to the first type semiconductor layer 121 and a second electrode 14 electrically connected to the second type semiconductor layer 123. Specifically, the first type semiconductor layer 121 and the second type semiconductor layer 123 are group III-V semiconductor layers having opposite doping types, such as p-type and n-type GaN layers. The light emitting layer 122 is capable of emitting light as a material having photoelectric property, such as a GaN layer, an InGaN layer, or an AlGaN layer. The first and second electrodes 13, 14 may be made of nickel (Ni), gold (Au), silver (Ag), copper (Cu), aluminum (Al), platinum (Pt), titanium (Ti), or molybdenum (Mo). For the instant embodiment, the first type semiconductor layer 121 and the second type semiconductor layer 123 are an n-type GaN layer and a p-type GaN layer formed by the MOCVD method, respectively. The light emitting layer 122 is an InGaN layer and the first and second electrodes 13, 14 are made of Au material.

The description above only illustrates specific embodiments and examples of the present invention. The present invention should therefore cover various modifications and variations made to the herein-described structure and operations of the present invention, provided they fall within the scope of the present invention as defined in the following appended claims.

What is claimed is:

1. A manufacturing method of a composite substrate, comprising the steps of:
providing a substrate; and
providing a precursor of group III elements and a precursor of nitrogen (N) element in an alternate manner to deposit a nitride buffer layer on the substrate by an atomic layer deposition (ALD) process or a plasma-enhanced atomic layer deposition (PEALD) process.

2. The manufacturing method as claimed in claim 1, wherein the substrate is constructed from a material selected from a group consisting of sapphire, silicon (Si), silicon carbide (SiC), gallium nitride (GaN), zinc oxide (ZnO), gallium arsenide (GaAs), scandium magnesium aluminate (ScAlMgO₄), strontium copper oxide (SrCu₂O₂), lithium dioxogallate (LiGaO₂), lithium aluminate (LiAlO₂), yttria-stabilized zirconia (YSZ), and glass, and wherein in the step of depositing the nitride buffer layer, the substrate is heated to a temperature in a range of 200 to 500° C.

3. The manufacturing method as claimed in claim 1, wherein in the step of alternately providing the precursor of group III elements and the precursor of N element to deposit the nitride buffer layer, the precursor of group III elements is selected from a group consisting of aluminum sec-butoxide, aluminum tribromide, aluminum trichloride, diethylaluminum ethoxide, tris(ethylmethylamido)aluminum, triethylaluminum, triisobutylaluminum, trimethylaluminum, tris(diethylamido)aluminum, tris(dimethylamino)aluminum, and tris(ethylmethylamido)aluminum, and wherein the precursor of N element is selected from a group consisting of ammonia (NH₃), ammonia plasma, and nitrogen-hydrogen plasma.

4. The manufacturing method as claimed in claim 1, wherein in the step of alternately providing the precursor of group III elements and the precursor of N element to deposit the nitride buffer layer, the precursor of group III elements is selected from a group consisting of trimethylgallium (TMGa), triethylgallium (TEGa), gallium tribromide (GaBr₃), gallium trichloride (GaCl₃), triisopropylgallium, and tris(dimethylamido)gallium, and wherein the precursor of N element is selected from ammonia (NH₃), ammonia plasma, and nitrogen-hydrogen plasma.

5. The manufacturing method as claimed in claim 1, wherein in the step of alternately providing the precursor of group III elements and the precursor of N element to deposit the nitride buffer layer, the precursor of group III elements is selected from a group consisting of trimethylindium (TMIn), indium(III)acetylacetonate, indium(I)chloride, indium(III)acetate hydrate, indium(II)chloride, and indium(III)acetate, and wherein the precursor of N element is selected from a group consisting of ammonia (NH₃), ammonia plasma, and nitrogen-hydrogen plasma.

6. The manufacturing method as claimed in claim 1, further comprising an annealing step after the step of alternately providing the precursor of group III elements and the precursor of N element to deposit the nitride buffer layer, wherein for the annealing step, the nitride buffer layer is annealed at a temperature in the range of 300 to 1600° C.

7. The manufacturing method as claimed in claim 1, further comprising an annealing step after the step of alternately providing the precursor of group III elements and the precursor of N element to deposit the nitride buffer layer, wherein for the annealing step, the nitride buffer layer is annealed at a temperature in the range of 400 to 1200° C.

8. The manufacturing method as claimed in claim 5, wherein in the step of alternately providing the precursor of group III elements and the precursor of N element to deposit the nitride buffer layer, the NH₃ gas is introduced at a flowrate in the range of 15 to 45 sccm.

9. The manufacturing method as claimed in claim 4, wherein in the step of alternately providing the precursor of group III elements and the precursor of N element to deposit the nitride buffer layer, the NH₃ gas is introduced at a flowrate in the range of 15 to 45 sccm.

10. The manufacturing method as claimed in claim 3, wherein in the step of alternately providing the precursor of group III elements and the precursor of N element to deposit the nitride buffer layer, the NH₃ gas is introduced at a flowrate in the range of 15 to 45 sccm.

11. The manufacturing method as claimed in claim 1, further comprising introducing hydrogen (H₂) gas in the step of alternately providing the precursor of group III elements and the precursor of N element to deposit the nitride buffer layer, wherein the flow rate of the H₂ gas is less than 10 sccm.

12. The manufacturing method as claimed in claim 1, wherein in the step of alternately providing the precursor of group III elements and the precursor of N element to deposit the nitride buffer layer, the pulse time of the precursor of group III elements is in the range of 0.03 to 0.25 second per deposition cycle.

13. A composite substrate, comprising:
a substrate and a nitride buffer layer deposited on a surface of the substrate, wherein the nitride buffer layer is formed by an atomic layer deposition (ALD) process or a plasma-enhanced atomic layer deposition (PEALD) process.

14. The composite substrate as claimed in claim 13, wherein the nitride buffer layer is an aluminum nitride (AlN) layer which is formed by alternately providing a precursor of group III elements and a precursor of nitrogen (N) element to deposit the nitride buffer layer, wherein the precursor of group III elements is selected from a group consisting of aluminum sec-butoxide, aluminum tribromide, aluminum trichloride, diethylaluminum ethoxide, tris(ethylmethylamido)aluminum, triethylaluminum, triisobutylaluminum, trimethylaluminum, tris(diethylamido)aluminum, tris(dimethylamino)aluminum, and tris(ethylmethylamido)aluminum, and wherein the precursor of N element is selected from a group consisting of ammonia (NH₃), ammonia plasma, and nitrogen-hydrogen plasma.

15. The composite substrate as claimed in claim 13, wherein the nitride buffer layer is a gallium nitride (GaN) layer which is formed by alternately providing a precursor of group III elements and a precursor of nitrogen (N) element to deposit the nitride buffer layer, wherein the precursor of group III elements is selected from a group consisting of trimethylgallium (TMGa), triethylgallium (TEGa), gallium tribromide (GaBr₃), gallium trichloride (GaCl₃), triisopropylgallium, and tris(dimethylamido)gallium, and wherein the precursor of N element is selected from a group consisting of ammonia (NH₃), ammonia plasma, or nitrogen-hydrogen plasma.

16. The composite substrate as claimed in claim 13, wherein the nitride buffer layer is an indium nitride (InN) layer which is formed by alternately providing a precursor of group III elements and a precursor of nitrogen (N) element to deposit the nitride buffer layer, wherein the precursor of group III elements is selected from a group consisting of trimethylindium (TMIn), indium(III)acetylacetonate, indium(I)chloride, indium(III)acetate hydrate, indium(II)chloride, and indium(III)acetate, and wherein the precursor of N element is selected from a group consisting of ammonia (NH₃), ammonia plasma, and nitrogen-hydrogen plasma.

17. The composite substrate as claimed in claim 13, wherein the substrate is made of a material selected from a group consisting of sapphire, silicon (Si), silicon carbide (SiC), gallium nitride (GaN), zinc oxide (ZnO), gallium arsenide (GaAs), scandium magnesium aluminate (ScAlMgO₄), strontium copper oxide (SrCu₂O₂), lithium dioxogallate (LiGaO₂), lithium aluminate (LiAlO₂), yttria-stabilized zirconia (YSZ), and glass.

18. A light emitting device, comprising:
a composite substrate including a substrate and a nitride buffer layer deposited on a surface of the substrate, wherein the nitride buffer layer is formed by an atomic layer deposition (ALD) process or a plasma-enhanced atomic layer deposition (PEALD) process; and
an epitaxial structure formed on the nitride buffer layer of the composite substrate.

19. The light emitting device as claimed in claim 18, wherein the nitride buffer layer is an aluminum nitride (AlN) layer which is formed by alternately providing a precursor of group III elements and a precursor of nitrogen (N) element to deposit the nitride buffer layer, wherein the precursor of group III elements is selected from a group consisting of aluminum sec-butoxide, aluminum tribromide, aluminum trichloride, diethylaluminum ethoxide, tris(ethylmethylamido)aluminum, triethylaluminum, triisobutylaluminum, trimethylaluminum, tris(diethylamido)aluminum, tris(dimethylamino)aluminum, and tris(ethylmethylamido)aluminum, and wherein the precursor of N element is selected from a group consisting of ammonia (NH₃), ammonia plasma, and nitrogen-hydrogen plasma.

20. The light emitting device as claimed in claim 18, wherein the nitride buffer layer is a gallium nitride (GaN) layer which is formed by alternately providing a precursor of group III elements and a precursor of nitrogen (N) element to deposit the nitride buffer layer, wherein the precursor of group III elements is selected from a group consisting of trimethylgallium (TMGa), triethylgallium (TEGa), gallium tribromide (GaBr₃), gallium trichloride (GaCl₃), triisopropylgallium, and tris(dimethylamido)gallium, and wherein the precursor of N element is selected from a group consisting of ammonia (NH₃), ammonia plasma, and nitrogen-hydrogen plasma.

21. The light emitting device as claimed in claim 18, wherein the nitride buffer layer is an indium nitride (InN) layer which is formed by alternately providing a precursor of group III elements and a precursor of nitrogen (N) element to deposit the nitride buffer layer, wherein the precursor of group III elements is selected from a group consisting of trimethylindium (TMIn), indium(III)acetylacetonate, indium(I)chloride, indium(III)acetate hydrate, indium(II)chloride, and indium(III)acetate, and wherein the precursor of N element is selected from a group consisting of ammonia (NH₃), ammonia plasma, and nitrogen-hydrogen plasma.

22. The light emitting device as claimed in claim 18, wherein the substrate is made of a material selected from a group consisting of sapphire, silicon (Si), silicon carbide (SiC), gallium nitride (GaN), zinc oxide (ZnO), gallium arsenide (GaAs), scandium magnesium aluminate (ScAlMgO₄), strontium copper oxide (SrCu₂O₂), lithium dioxogallate (LiGaO₂), lithium aluminate (LiAlO₂), yttria-stabilized zirconia (YSZ), and glass.

23. The light emitting device as claimed in claim 22, wherein the epitaxial structure includes a first type semiconductor layer formed on the nitride buffer layer, a light emitting layer formed on the first type semiconductor layer, and a second type semiconductor layer formed on the light emitting layer.
